(19) United States
(12) Patent Application Publication
(10) Pub. No.: US 2016/0105272 A1
(43) Pub. Date: Apr. 14, 2016

(54) Systems and Methods for Leak Suppression in a Full Duplex System

(71) Applicant: Huawei Technologies Co., Ltd., Shenzhen (CN)

(72) Inventors: James Gary Griffiths, Braeside (CA); Wolfgang Oberhammer, Ottawa (CA); Huan Wu, Kanata (CA); Eddy Shi-Ning Hum, Ottawa (CA)

(21) Appl. No.: 14/882,047

(22) Filed: Oct. 13, 2015

Related U.S. Application Data
(60) Provisional application No. 62/063,860, filed on Oct. 14, 2014.

(51) Int. Cl. H04L 5/14; H03H 7/38; H01P 1/38

(52) U.S. Cl. CPC H04L 5/14; H01P 1/38; H03H 7/38

(57) ABSTRACT

A system and method for leak suppression in a full duplex system is disclosed. In an embodiment, a system for wireless transmission and reception includes a circulator having a common port, an input port and an output port; a conjugate matching tuner coupled to the common port; and an antenna coupled to the conjugate matching tuner, an impedance of the antenna being conjugate matched to an impedance of the common port of the circulator by the conjugate matching tuner.

This application claims the benefit of U.S. Provisional Application No. 62/063,860, filed on Oct. 14, 2014 which application is hereby incorporated herein by reference.

### TECHNICAL FIELD

The present invention relates to a system and method for full duplex communication, and, in particular embodiments, to a system and method for leak suppression in full duplex communication.

### BACKGROUND

In a full duplex system, data is transmitted and received over the same frequency or channel at the same time. A big challenge in full duplex transmission is to suppress the transmitter leak into the receiver that is co-located and at the same frequency.

### SUMMARY

An embodiment system for wireless transmission and reception includes a circulator having a common port, an input port and an output port; a conjugate matching tuner coupled to the common port; and an antenna coupled to the conjugate matching tuner, an impedance of the antenna being conjugate matched to an impedance of the common port of the circulator by the conjugate matching tuner.

An embodiment network component includes a circulator comprising an input port, a output port, and a common port; a transmitter connected to the input port of the circulator; a voltage standing wave ratio (VSWR) tuner comprising a first port and a second port, the first port connected to the common port of the circulator; a receiver connected to the output port of the circulator; and an antenna connected to the second port of the VSWR tuner, wherein the VSWR tuner substantially minimizes a leak of a transmission signal into the receiver.

An embodiment method for manufacturing a full duplex system includes connecting a first port of a conjugate matching tuner to a common port of a circulator; and connecting a second port of the conjugate matching tuner to an antenna, an impedance of the antenna being conjugate matched to an impedance of the common port of the circulator by the conjugate matching tuner. In an embodiment, the method also includes connecting a transmitter to an input port of the circulator.

An embodiment method for transmitting and receiving a signal in a full duplex wireless device includes transmitting a transmitted signal to an input port of a circulator having a common port, the input port and an output port; and conjugately matching an impedance of the common port of the circulator with an impedance of an antenna thereby reducing reflection of the transmitted signal appearing at the output port of the circulator.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates major sources of transmitter leak in an FD system;

FIG. 2 illustrates a conjugate matching tuner inserted between the circulator and antenna in an FD system;

FIG. 3 illustrates minimizing transmission S21 by adjusting the stub tuner;

FIG. 4 illustrates S21 of the setup in FIG. 3 after tuning for minimum S21;

FIG. 5 illustrates breaking open the setup to measure S11 of the tuner/antenna assembly;

FIG. 6 illustrates measured S11 of the assembly shown in FIG. 5;

FIG. 7 illustrates setup used to match to a simulated antenna VSWR;

FIG. 8 illustrates S21 with a 6 dB return loss load;

FIG. 9 illustrates S11/S22 of tuner/6 dB return loss load assembly;

FIG. 10 illustrates S21 with a 12 dB return loss load;

FIG. 11 illustrates S11/S22 of tuner/12 dB return loss load assembly;

FIG. 12 illustrates S21 with a 20 dB return loss load;

FIG. 13 illustrates S11/S22 of tuner/20 dB return loss load assembly;

FIG. 14 illustrates setup used to measure cancellation using a continuously variable phase shifter & attenuator;

FIG. 15 illustrates tuning for minimum S21 using a phase shifter and attenuator;

FIG. 16 illustrates setup used to generate and measure the spectrum of an LTE like signal appearing at the port 3 (RX Port) of the circulator;

FIG. 17 illustrates LTE like reference signal spectrum appearing at port 1 of circulator, used to test the circulator/tuner/antenna assembly of FIG. 16;

FIG. 18 illustrates signal spectrum appearing at the port 3 (RX Port) of circulator using setup shown in FIG. 16;

FIG. 19 illustrates adjusting the tuner for a flatter response in the leak appearing at port 3 (RX port) of the circulator;

FIG. 20 illustrates setup used to measure transmission loss (S21& S12) including antennas in a mini chamber;

FIG. 21 illustrates S21/S12 using the vertical polarizations of the “flower pot” antennas using the setup of FIG. 20;

FIG. 22 illustrates S21/S12 using the horizontal polarizations of the “flower pot” antennas using the setup of FIG. 20;

FIG. 23 illustrates setup to measure S21 of the VSWR tuner only;

FIG. 24 illustrates setup to measure S12 of the VSWR tuner only;

FIG. 25 illustrates S21/S12 of the VSWR tuner;

FIG. 26 illustrates un-normalized measurement of S21 in mini chamber, including tuner+chamber+antenna;

FIG. 27 illustrates parameterized model of a digitally tuned capacitor;

FIG. 28 illustrates using the model of FIG. 27 in a 4 stub tuner with simulated antenna impedances of Table 2;

FIG. 29 illustrates results of optimizing for minimum S11 in the stub tuner of FIG. 28;

FIG. 30 illustrates stub tuner of FIG. 29 attached to measured antenna and circulator S parameters;

FIG. 31 illustrates results of optimizing for minimum S21 in the stub tuner of FIG. 30;

FIG. 32 is a flowchart of an embodiment method 3200 for manufacturing an embodiment FD device;

FIG. 33 illustrates a block diagram of an embodiment processing system for performing methods described herein, which may be installed in a host device; and

FIG. 34 illustrates a block diagram of a transceiver adapted to transmit and receive signaling over a telecommunications network.

### DETAILED DESCRIPTION OF ILLUSTRATIVE EMBODIMENTS

The structure, manufacture and use of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Disclosed herein are systems and methods that employ devices such as stub tuners and other conjugate matching devices to improve the voltage standing wave ratio (VSWR) of an antenna in order to achieve maximum power transfer. An embodiment uses a conjugate match tuner to maximize leak suppression in a band of interest by tuning, not for best VSWR, but for minimum leak as it would exist in a full duplex (FD) system. An embodiment improves reflection by conjugate matching the two components that are responsible for the major reflections in the system, thereby limiting transmitter leakage into the receiver.

An embodiment method provides for manufacturing a full duplex system including a circulator having a common port, an input port and an output port; a conjugate matching tuner coupled to the common port; and an antenna coupled to the conjugate matching tuner. The method includes connecting an output of a vector network analyzer (VNA) to the input port, connecting an input of the VNA to the output port, sweeping the input port with the VNA, and adjusting the tuner for minimum transmission at the output port during the sweeping, thereby conjugate matching the antenna and the common port of the circulator.

An embodiment full duplex system includes a circulator having a common port, an input port and an output port. The system further includes a transmitter coupled to the input port, a receiver coupled to the output port, a stub tuner coupled to the common port, and an antenna coupled to the stub tuner, wherein the antenna is conjugate matched to the common port of the circulator by the stub tuner.

The two major sources of leak in within the transceiver of a FD system consist of leak through the circulator due to finite isolation and reflected power from the antenna due to finite return loss. Typical values of circulator isolation are 18 to 22 dB for commonly available circulators. More isolation can be had but at considerably more expense. Antenna return losses range hugely but a good minimum value to use, especially in a broadband antenna is 15-18 dB. Therefore the combined leak due to these two paths can be quite high, as high as −12 to −15 dB.

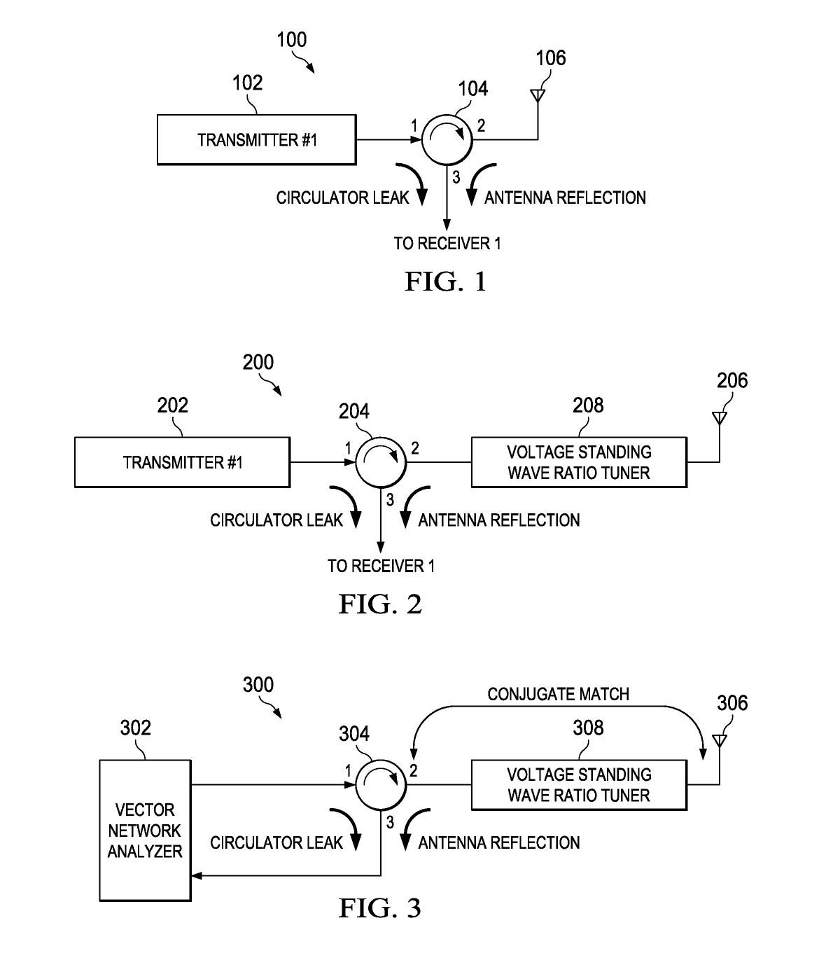

FIG. 1 is a block diagram of a prior art FD system 100. System 100 includes a transmitter 102, a circulator 104, and an antenna 106. The circulator 104 has three ports labeled 1, 2, and 3. FIG. 1 illustrates these two paths that are the major sources of transmitter leak in an FD system. One path is circulator leak and one path is the antenna reflection.

It has been found that by conjugately matching the common port (antenna port) of a three port circulator, it is possible to greatly increase the isolation between the remaining two (transmit & receive) ports [1].

A VSWR tuner (e.g., a sliding stub, a double stub, a triple stub, etc.) may then be inserted between the common port of the circulator and the antenna which can be used to conjugately match the impedance of the circulator to the antenna impedance.

FIG. 2 is a block diagram illustrating an embodiment FD system 200. FD system 200 illustrates a conjugate matching tuner inserted between the circulator and antenna in an FD system. The system 200 includes a transmitter 202, a circulator 204, an antenna 206, and a VSWR tuner 208. The transmitter is connected to the input port (labeled “1”) of the circulator 204. A first port of the VSWR tuner 208 is connected to the common port (labeled “2”) of the circulator and a second port of the VSWR tuner 208 is connected to the antenna 206. The VSWR tuner 208 is adjusted, not for best VSWR, but for minimum leak of the transmitted signal into the receiver as it would exist in a full duplex (FD) system. In an embodiment, the VSWR tuner is adjusted dynamically during operation as conditions change. In an embodiment, the VSWR tuner 208 substantially conjugately matches the impedance of the circulator 204 with the impedance of the antenna 206. In particular, the VSWR tuner 208 matches the impedance of the common port of the circulator 204 with the antenna 206. In various embodiments, the VSWR tuner 208 may be a stub tuner or a mechanical tuner. In embodiments, the stub tuner may be a sliding stub tuner, a double stub tuner, or a triple stub tuner.

One problem in adjusting the VSWR tuner 208 is that the return loss of the assembly (circulator+tuner+antenna) is not directly available to measure and use as an error signal because of the circulator properties. In an embodiment, the internal impedances of the VSWR tuner 208 are adjusted either by varying the values of lumped element components or by the adjustment of distributed element components such as transmission lines.

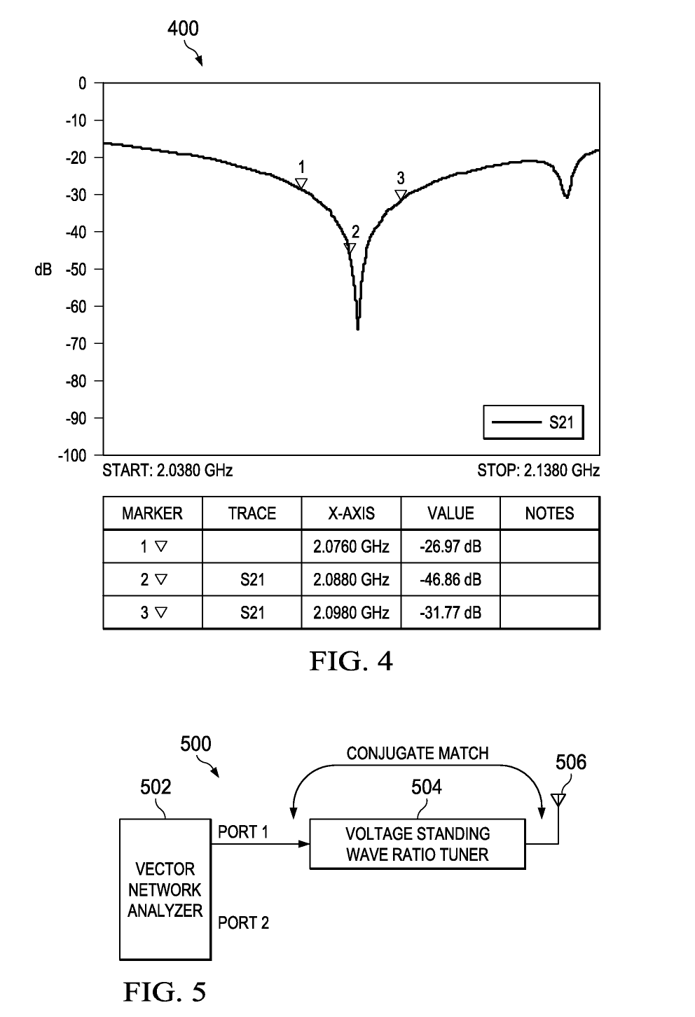

However, if a vector network analyzer (VNA) used to sweep port 1 (TX) of the circulator and adjust the tuner for minimum transmission at port 3 (RX), while port 2 (ANT) is connected to the antenna via the tuner as shown in FIG. 3, one is able to get the S21 response as shown in FIG. 4.

FIG. 3 is a block diagram illustrating a system 300 for minimizing transmission S21 by adjusting the stub tuner. System 300 includes a VNA 302, a circulator 304, an antenna 306, and a VSWR tuner 308. One port of the VNA 302 is connected to the input port (labeled “1”) of the circulator 304 and a second port of the VNA 302 is connected to the output port (labeled “3”) of the circulator 304. The common port (labeled “2”) of the circulator 304 is connected to a first port of the VSWR tuner 308. A second port of the VSWR tuner 308 is connected to the antenna 306.

FIG. 4 is a graph 400 illustrating S21 of the setup in FIG. 3 after tuning for minimum S21.

FIG. 5 is a diagram of a system 500 for determining whether a conjugate impedance match exists between the two ports of a VSWR tuner. System 500 is similar to system 300 except that the circulator 308 is removed. System 500 includes a VNA 502 with a first port connected to a first port of a VSWR tuner 504. The second port of the VSWR tuner 504 is connected to the antenna 506. Thus, with the setup of FIG. 3 reconfigured with the circulator removed as shown in FIG. 5, it can be determined whether there still is a good match.

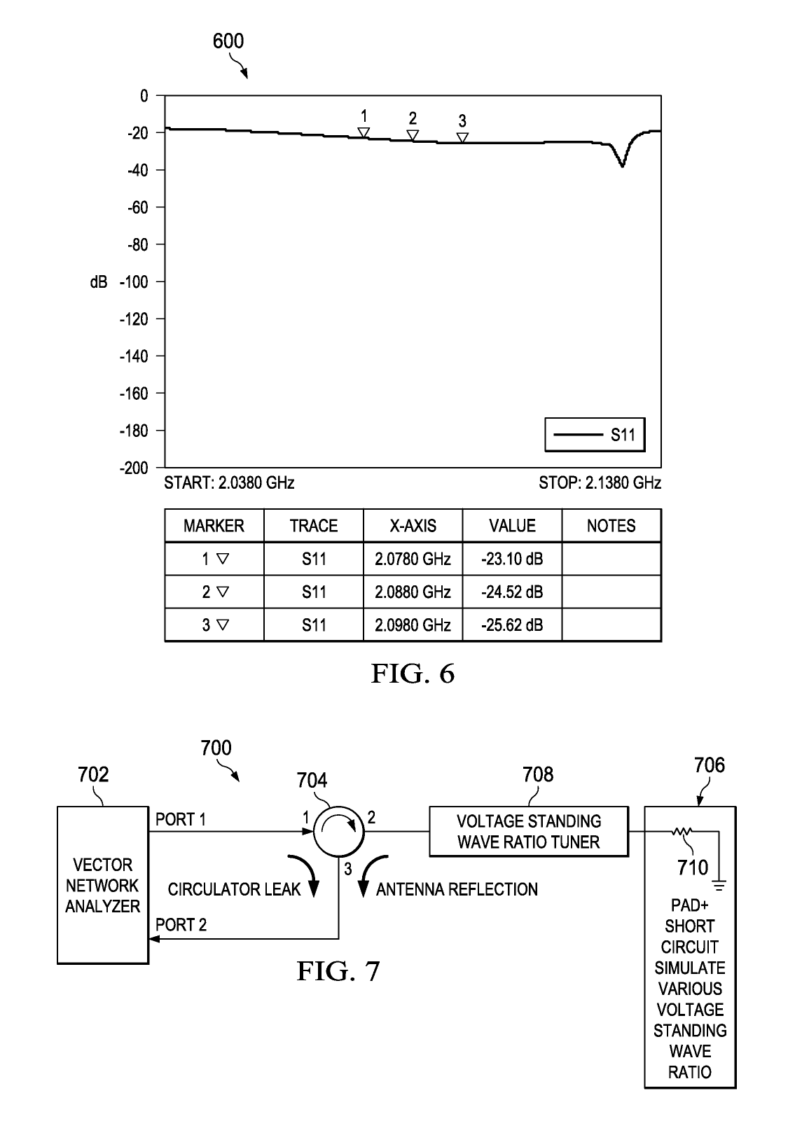

FIG. 6 is a graph 600 of S11 of the setup of FIG. 5. FIG. 5 illustrates breaking open the setup to measure S11 of the tuner/antenna assembly, and FIG. 6 illustrates measured S11 of the assembly shown in FIG. 5.

As can be seen in FIG. 6, a very good return loss is still present. Similarly measuring the other way, into the tuner/circulator assembly shows a very good return loss as well. It can be concluded that minimizing S21 in FIG. 3 provides a conjugate match of the common port (ANT) of the circulator 304 and the antenna 306.

In this manner once can simultaneously achieve a minimum S21 of FIG. 4 and the good S11 of FIG. 6. To prove this is not accidental reflection of power from the antenna which is of the correct magnitude and phase to cancel the leak of the circulator, a matching exercise was performed using the circulator 204, 304 and simulated the antenna return loss with loads representing various return losses from 6 dB all the way to 20 dB, using 50 ohm pads and a short circuit. Regardless of the return loss, in an embodiment, one is always able to minimize S21 while simultaneously providing good return loss, S11/S22, through the tuner/antenna assembly.

FIG. 7 is a block diagram of a system 700 that shows the setup used to perform this test. Table 1, below, lists the values of pads and return losses simulated and their related plots. System 700 includes a VNA 702, a circulator 704, a VSWR tuner 708, and a pad+short circuit 706 to simulate various VSWR. Port 1 of the VNA 702 is connected to the input port (labeled “1”) of the circulator 704. The output port (labeled “3”) of the circulator 704 is connected to port 2 of the VNA 702. The common port (labeled “2”) of the circulator 704 is connected to a first port of the VSWR tuner 708. A second port of the VSWR tuner 708 is connected to the pad+short circuit 706.

TABLE 1

| Pad Value | Return Loss | FIG. # of S21 | FIG. # of S11 |
|---|---|---|---|
| 3 | 6 | 8 | 9 |
| 6 | 12 | 10 | 11 |
| 10 | 20 | 12 | 13 |

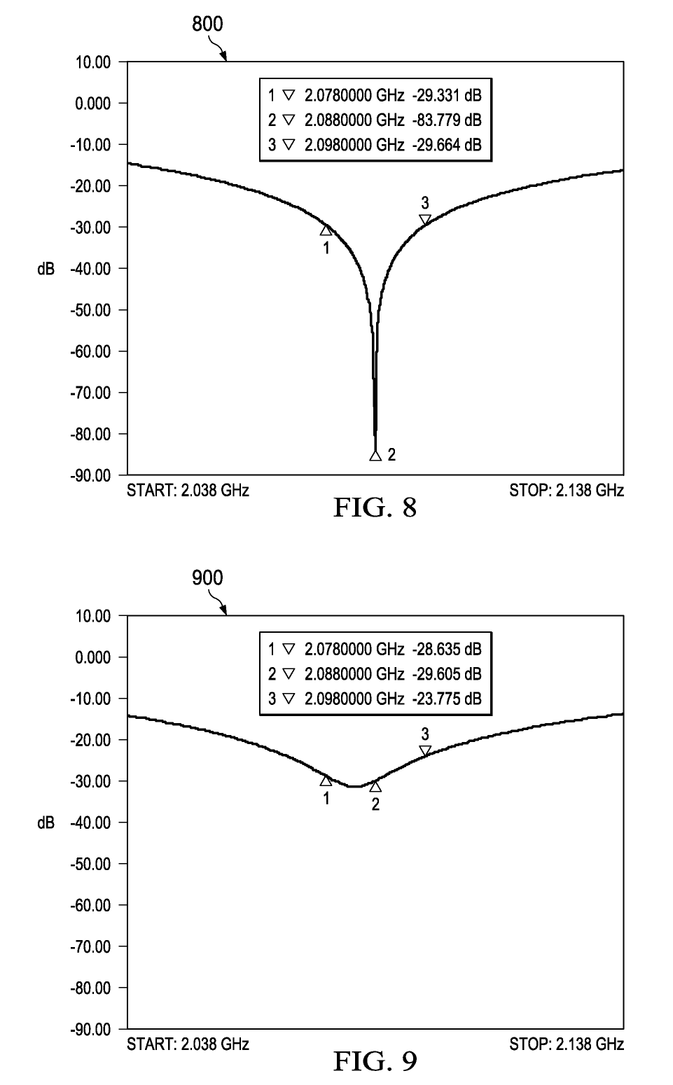

FIG. 8 is a graph 800 illustrating S21 with a 6 dB return loss load.

FIG. 9 is a graph 900 illustrating S11/S22 of tuner/6 dB return loss load assembly.

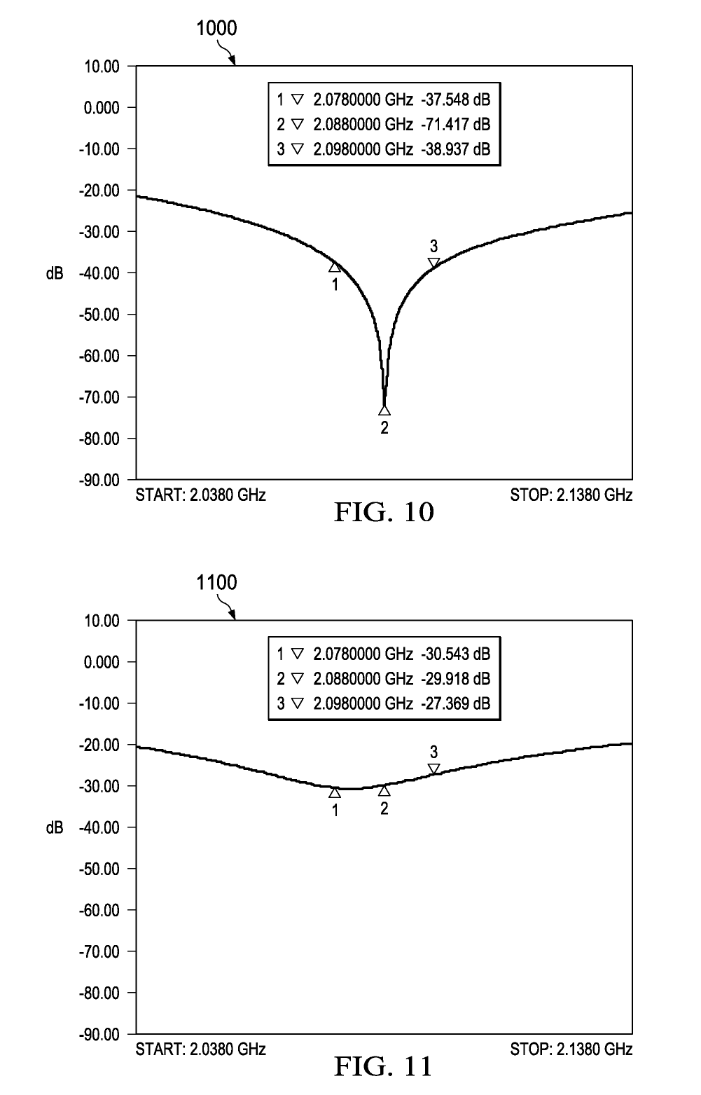

FIG. 10 is a graph 1000 illustrating S21 with a 12 dB return loss load.

FIG. 11 is a graph 1100 illustrating S11/S22 of tuner/12 dB return loss load assembly.

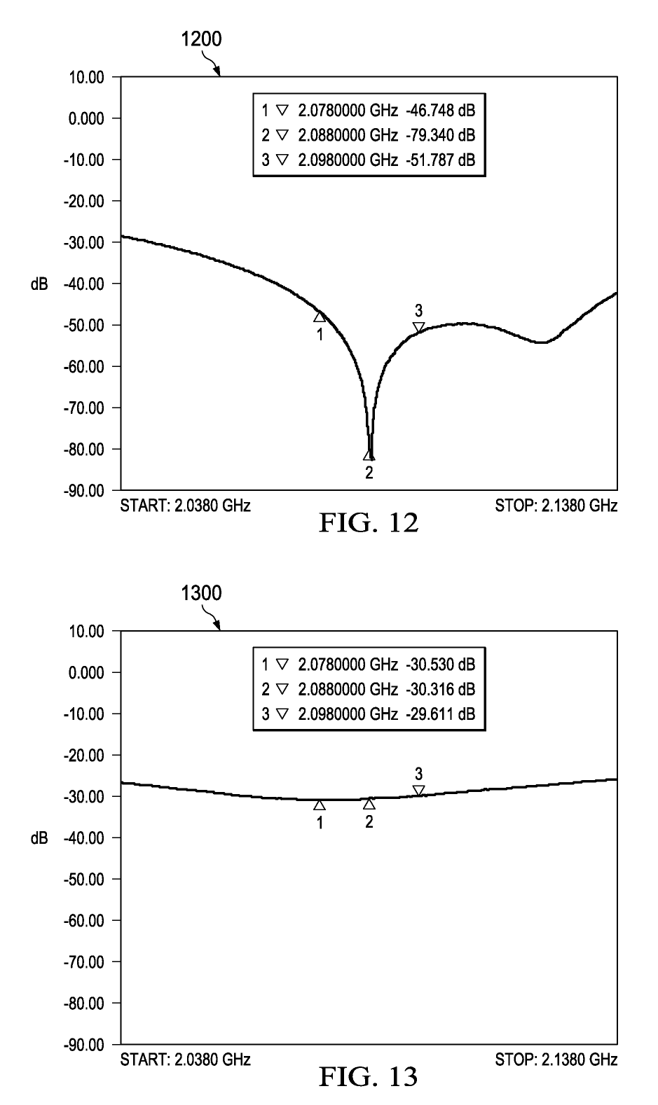

FIG. 12 is a graph 1200 illustrating S21 with a 20 dB return loss load.

FIG. 13 is a graph 1300 illustrating S11/S22 of tuner/20 dB return loss load assembly.

As a cross check, cancelling a carrier signal using a continuously variable attenuator and phase shifter was also tried.

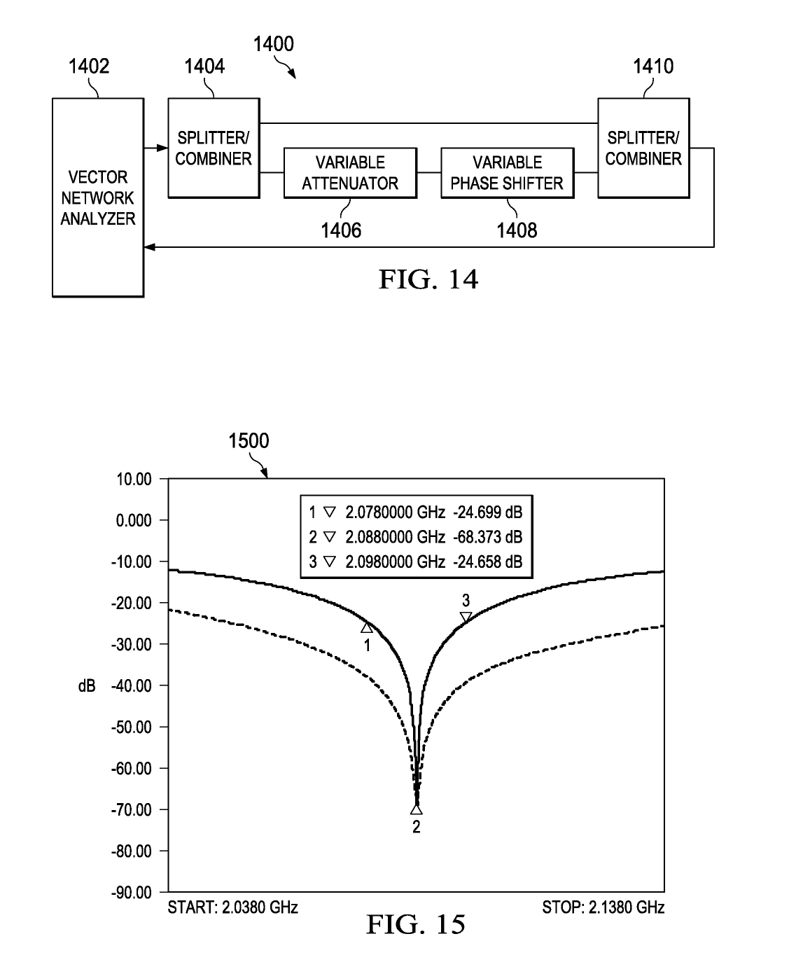

FIG. 14 is a block diagram of a system 1400 used to measure cancellation using a continuously variable phase shifter & attenuator. System 1400 includes a VNA 1402, a first splitter/combiner 1404, a variable attenuator 1406, a variable phase shifter 1408, and a second splitter/combiner 1410. An output port of the VNA 1402 is connected to an input port of the first splitter combiner 1404. A first output port of the first splitter/combiner 1404 is connected to a first input port of the second splitter/combiner 1410. A second output port of the splitter/combiner 1404 is connected to the input of the variable attenuator 1406. The output of the variable attenuator 1406 is connected to the input of the variable phase shifter 1408. The output of the variable phase shifter 1408 is connected to a second input of the second splitter/combiner 1410. The output of the second splitter/combiner 1410 is connected to an input port of the VNA 1402.

It was found that this method of cancellation seems to be providing narrow band results compared to the disclosed VSWR tuner method described above.

FIG. 15 is a graph 1500 that illustrates comparative plots for tuning for minimum S21 using a phase shifter and attenuator. (Note that the stored [wider BW] trace is of a minimum S21 using a Stub Tuner).

Next, an LTE-like broadband signal (16 QAM OFDM, PAPR of 10.5 dB, 18 MHz 99% bandwidth occupancy) was generated and applied that to the circulator/tuner/antenna combination that was tuned for minimum S21 shown in FIG. 3.

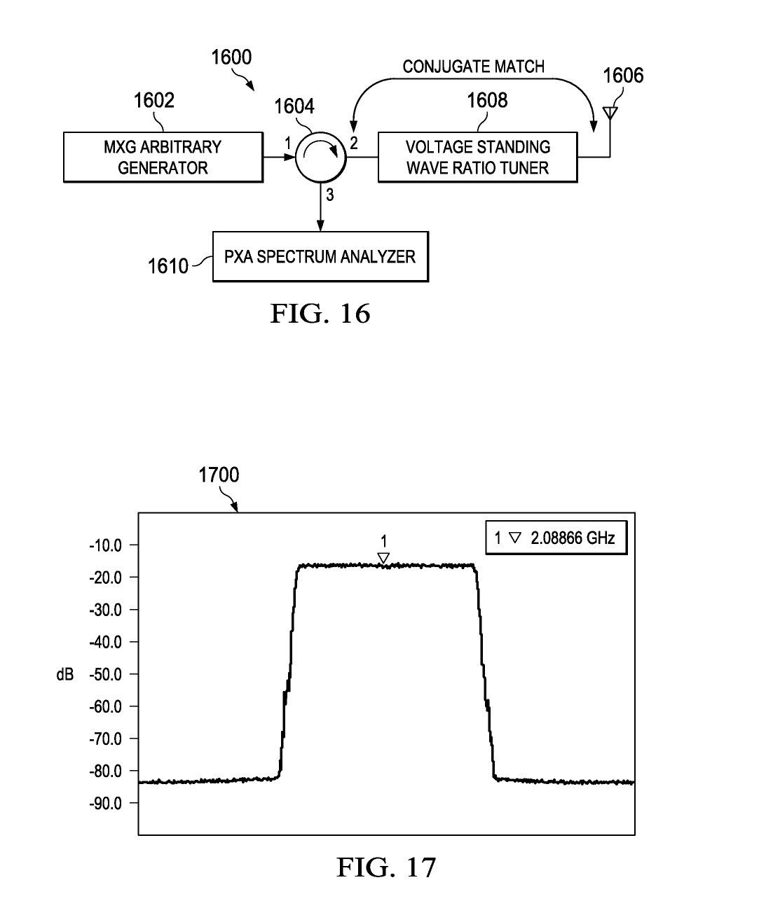

FIG. 16 is a block diagram of a system 1600 used to generate and measure the spectrum of an LTE like signal appearing at the port 3 (RX Port) of the circulator, and FIGS. 17-19 show the results. System 1600 includes an MXG arbitrary generator 1602, a circulator 1604, a VSWR tuner 1608, an antenna 1606, and a PXA spectrum analyzer 1610. The output of the MXG arbitrary generator 1602 is connected to the input port (labeled “1”) of the circulator 1604. The common port (labeled “2”) of the circulator 1604 is connected to a first port of the VSWR tuner 1608. The output port (labeled “3”) of the circulator is connected to the PXA spectrum analyzer 1610. The second port of the VSWR tuner 1608 is connected to the antenna 1606.

FIG. 17 is a graph 1700 that illustrates LTE like reference signal spectrum appearing at port 1 of circulator, used to test the circulator/tuner/antenna assembly of system 1600 of FIG. 16.

As expected, the shape of the signal spectrum tracks the shape of the VNA S21 response shown in the VNA section described above (V notch). Overall, in an embodiment, a leak suppression of about 36 dB was achieved.

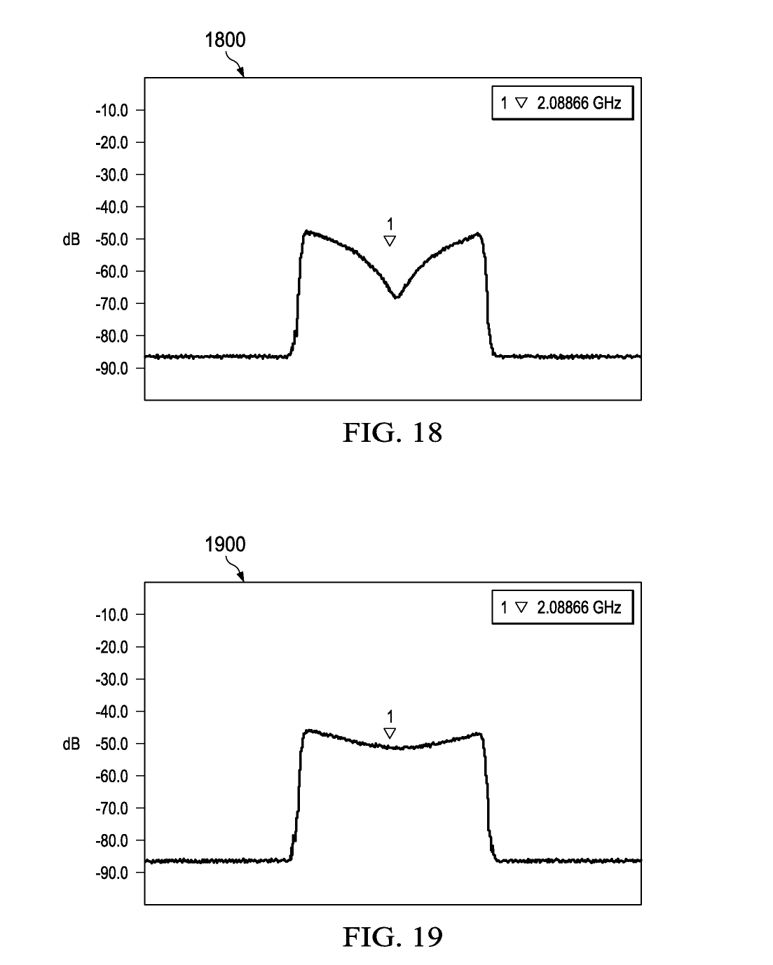

FIG. 18 is a graph 1800 that illustrates signal spectrum appearing at the port 3 (RX Port) of circulator 1604 using setup of system 1600 shown in FIG. 16 (No retuning between the VNA setup and the LTE signal setup).

If desired, it is possible to adjust the VSWR tuner 1608 for a flatter response with slightly less isolation (32 versus 36 dB) across the band, as shown in FIG. 19, which is a graph 1900 that illustrates adjusting the tuner for a flatter response in the leak appearing at port 3 (RX port) of the circulator 1604. (Retuned for a flatter response).

To determine the true insertion loss of the tuner in this assembly, the antenna was installed in a mini anechoic chamber with a matching antenna at the other end of the chamber. This allows one to measure both transmission loss and receive loss while removing the radiation efficiency of the antenna from the measurement.

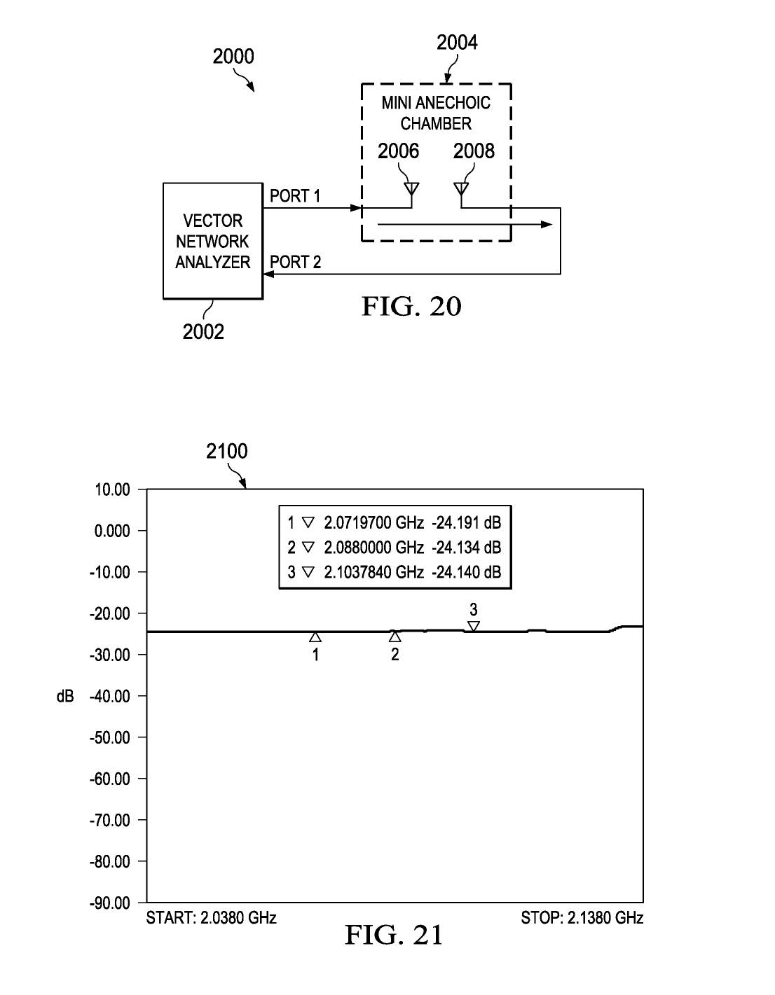

FIG. 20 is a block diagram of a system 2000 for determining the true insertion loss. FIG. 20 illustrates setup used to measure transmission loss (S21& S12) including antennas in a mini chamber. System 2000 includes a VNA 2002 and a mini anechoic chamber 2004. The mini anechoic chamber 2004 includes two antennas 2006, 2008. The output port (Port 1) of the VNA 2002 is connected to the first antenna 2006 and the input port (Port 2) of the VNA 2002 is connected to the second antenna 2008.

Firstly, the antennas 2006, 2008, chamber and associated cables, are characterized using the setup shown in FIG. 20. Then the S21 & S12 traces are normalized to zero out the loss of the circulator, cables, antenna 2006, 2008 and chamber 2004. This becomes the reference for making S21 and S12 measurements, when adding the VSWR tuner.

FIG. 21 is a graph 2100 that illustrates S21/S12 using the vertical polarizations of the “flower pot” antennas using the setup of FIG. 20.

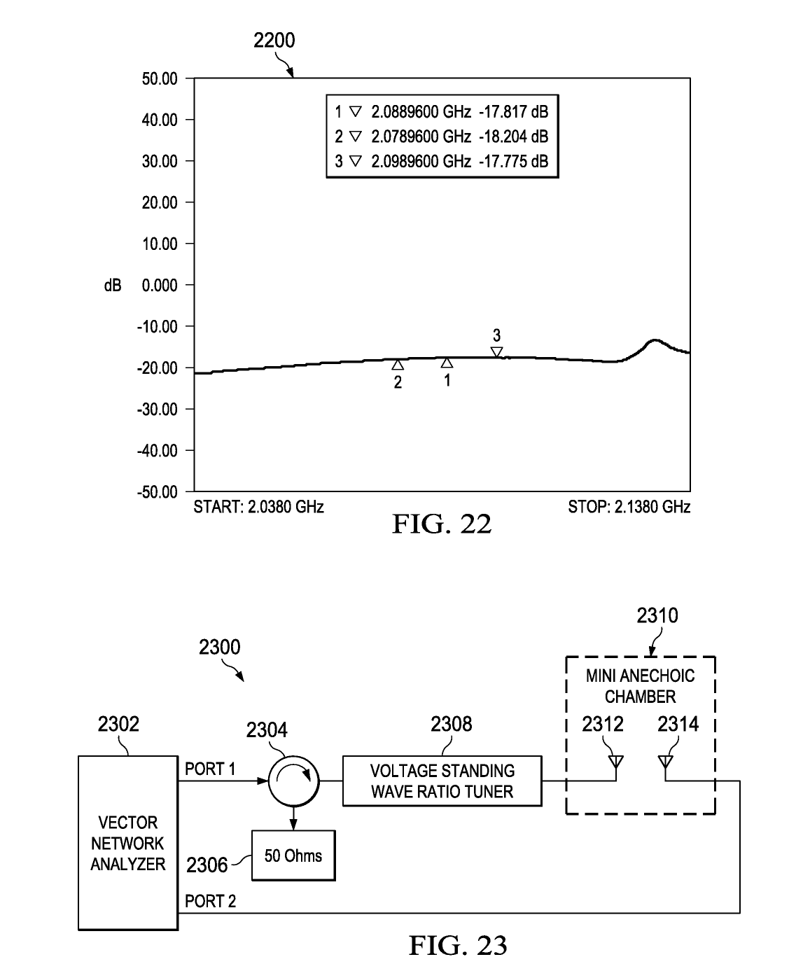

FIG. 22 is a graph 2200 that illustrates S21/S12 using the horizontal polarizations of the “flower pot” antennas using the setup of FIG. 20.

Next, choosing the antenna vertical polarization connections, the VSWR tuner was added to the assembly of FIG. 20 and the tuner adjusted for minimum transmission at the output port of the circulator, as done before, using the VNA setup of FIG. 3.

Next the VNA connections were moved as shown in FIG. 23, in order to measure S21. (The VNA trace was first normalized to zero out the loss of the circulator, antenna, cables and chamber).

FIG. 23 is a block diagram of an embodiment system 2300 that illustrates setup to measure S21 of the VSWR tuner only (all else is normalized to 0 dB). System 2300 includes a VNA 2302, a circulator 2304, a VSWR tuner 2308, a mini anechoic chamber 2310, and a load 2306. Port 1 of the VNA 2302 is connected to an input port of the circulator 2304. The common port of the circulator 2304 is connected to the VSWR tuner 2308 and the output port of the circulator 2304 is connected to the load 2306. In the depicted embodiment, the load 2306 is a 50 ohm load. The mini anechoic chamber 2310 includes two antennas 2312, 2314.

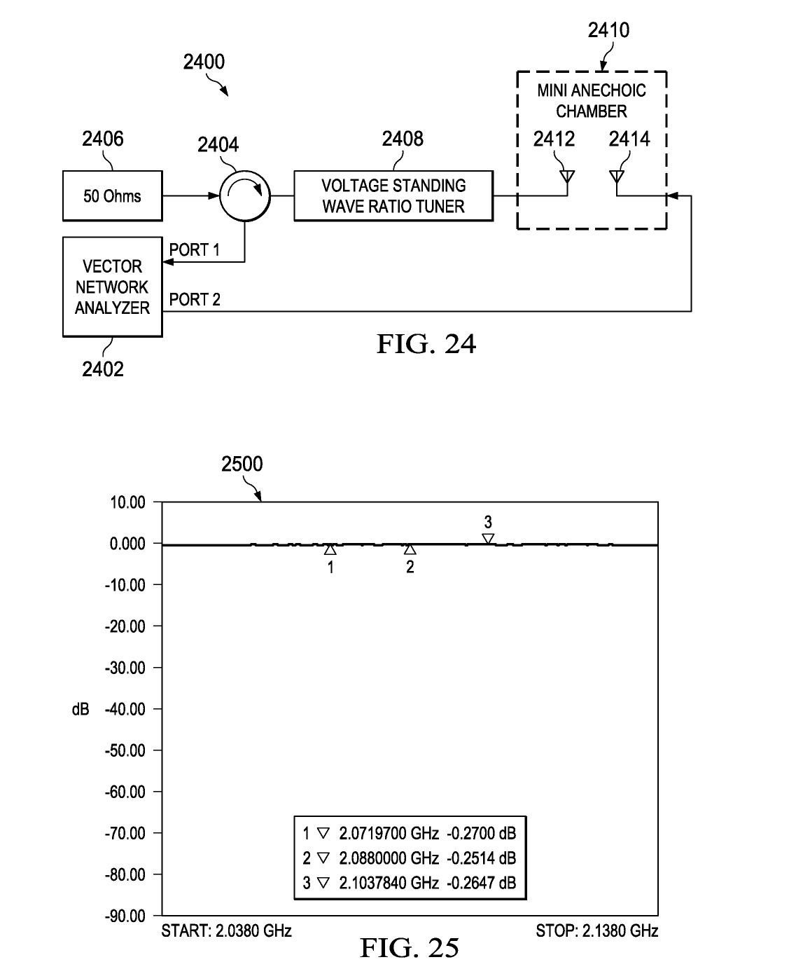

FIG. 24 is a block diagram of an embodiment system 2400 that illustrates a setup to measure S12 of the VSWR tuner only (all else is normalized to 0 dB). System 2400 includes a load 2406, a circulator 2404, a VSWR tuner 2408, a mini anechoic chamber 2410, and a VNA 2402. The mini anechoic chamber 2410 includes two antennas 2412, 2414. The load 2406 is connected to the input port of the circulator 2404. In the depicted embodiment, the load is a 50 ohm load. The common port of the circulator 2404 is connected to a first port of the VSWR tuner 2408. The output port of the circulator 2404 is connected to the input port (Port 1) of the VNA 2402. The second port of the VSWR tuner 2408 is connected to the first antenna 2412. The second antenna 2414 is connected to an output port (Port 2) of the VNA 2402.

Finally, the VNA connections were moved in order to measure S12 using the assembly shown in FIG. 24.

FIG. 25 is a graph 2500 that illustrates S21/S12 of the VSWR tuner (all else is normalized to 0 dB).

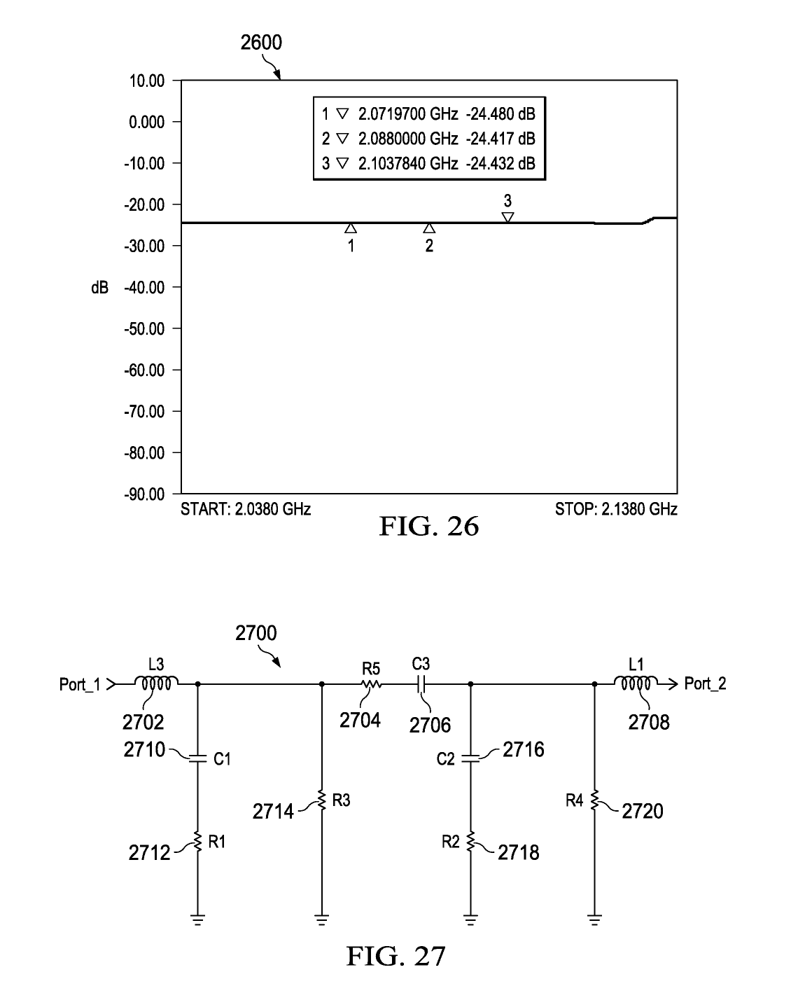

The normalized (setup insertion loss minus the tuner is zeroed out) measured S21 & S12 of the tuner is shown in the FIG. 25. The insertion loss is on the order of 0.3 dB in either direction. The un-normalized measured S21 is shown for reference in FIG. 26 below.

FIG. 26 is a graph 2600 that illustrates un-normalized measurement of S21 in mini chamber, including tuner+chamber+antenna.

With respect to design simulations, to explore further whether or not more tuning elements could help to increase bandwidth, a Genesys model was built using the PE64908 digitally tunable capacitor (DTC). Although this device does not have adequate linearity to provide IMD3 low enough to not desensitize the UE receive signal, it does serve to illustrate the concept.

FIG. 27 is a schematic diagram of a system 2700 of a Genesys model. The parameterized model of a digitally tuned capacitor shown in FIG. 27 was built using the detailed model parameters given in the Peregrine PE64908 data sheet. The system 2700 includes inductor 2702, resistor 2704, capacitor 2706, inductor 2708, capacitor 2710, capacitor 2716, and resistors 2712, 2714, 2718, 2720. The components of the system 2700 may be arranged as shown in FIG. 27.

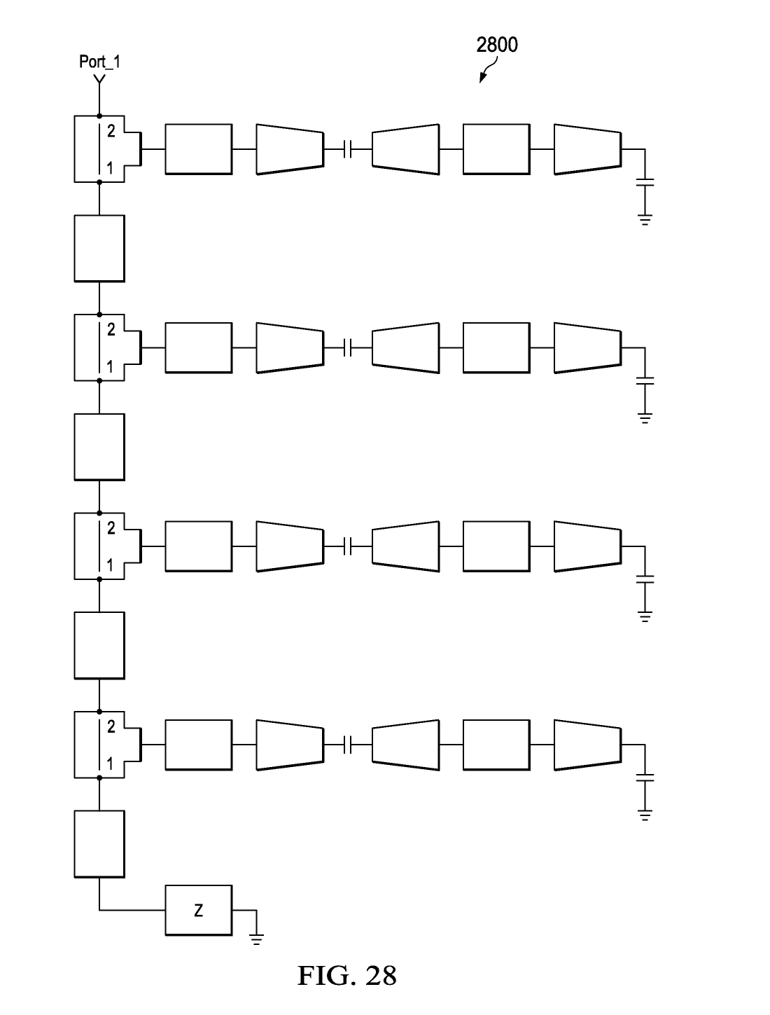

FIG. 28 is a diagram of a system 2800 design that was simulated to determine how well one can match an antenna impedance with the following characteristics, which roughly follow a 10 dB return loss circle on the Smith chart.

Table 2 below shows various complex impedances used to test the matching capabilities of a 4 stub tuner.

TABLE 2

| Real | Imaginary |
|---|---|
| 50 | −j32 |
| 50 | +j32 |
| 26 | j0 |
| 98 | j0 |
| 34 | +j25 |
| 34 | −j25 |
| 78 | −j34 |
| 78 | +j34 |
| 31 | +j18 |
| 31 | −j18 |

FIG. 28 illustrates using the model of FIG. 27 in a 4 stub tuner with simulated antenna impedances of Table 2.

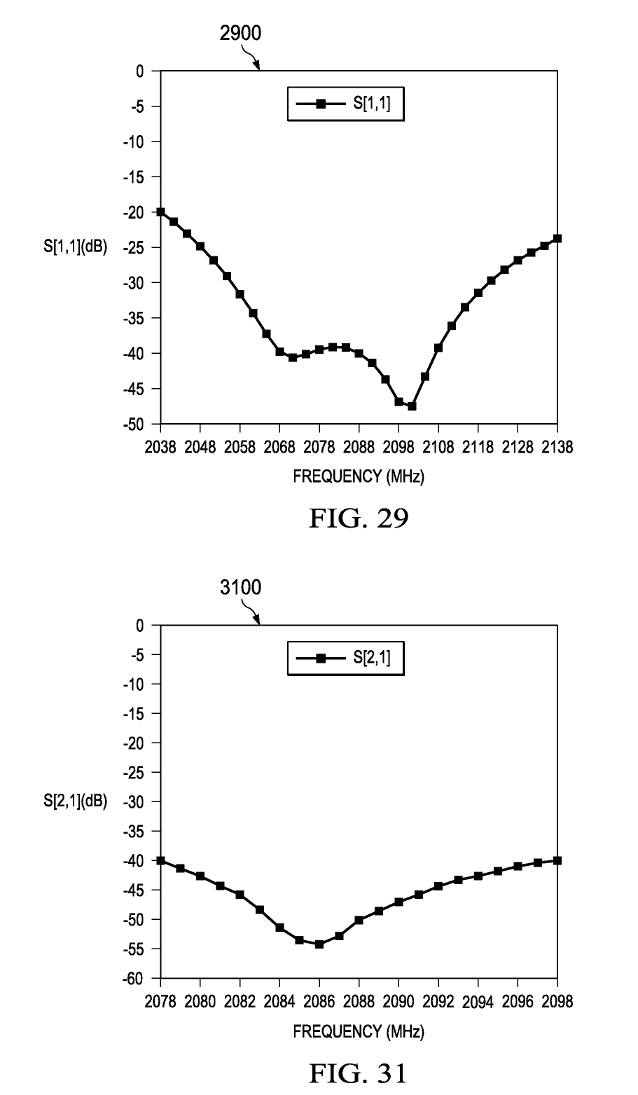

The results of optimizing for return loss (S11) are shown in FIG. 29, which is a graph 2900 that illustrates results of optimizing for minimum S11 in the stub tuner of FIG. 28

Finally a circuit was built using measured S parameters of the three port circulator and the “flowerpot” antenna and the circuit optimized for minimum S21. Unfortunately the measured S parameters of the circulator extend only across the operational band, but one can see it is possible to match to −30 dB return loss across a bandwidth of 60 or more MHz with 4 stubs. It may be possible to match to 100 MHz to 200 MHz or more with a better topology

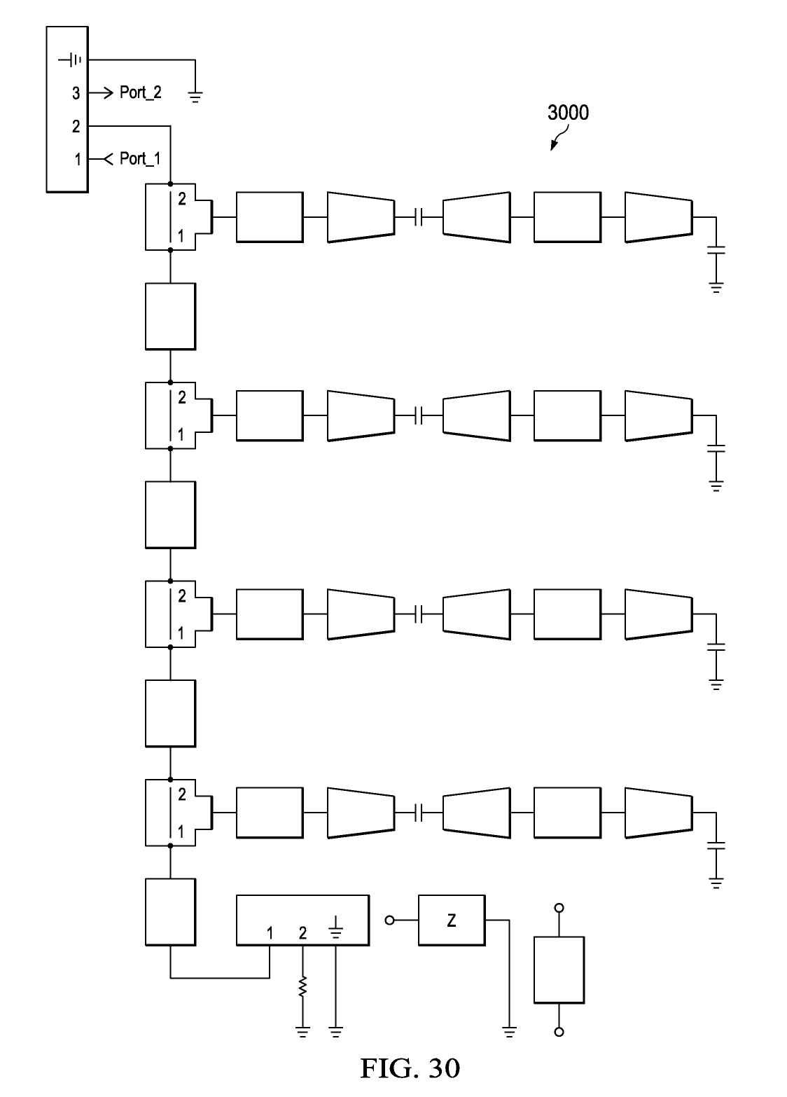

FIG. 30 is a diagram of a system 3000 that illustrates the stub tuner of FIG. 29 attached to measured antenna and circulator S parameters.

FIG. 31 is a graph 3100 that illustrates results of optimizing for minimum S21 in the stub tuner of FIG. 30.

In summary, tuning for minimum leak at port 3 (RX port) results in a reduction in leak from port 1 (TX port) to Port 3 (RX port) and provides for excellent match at both the port 2 (ANT port) of the circulator as well as an excellent match into the antenna itself. Because of this, the added through path insertion loss in both the transmit and receive directions is very low as verified in the mini anechoic chamber.

In addition, it is shown that the shape of the transmission response is superimposed on a broadband modulated signal but suppressed by more than 35 dB. It is also possible to tune the VSWR to achieve a somewhat flatter suppression response if required.

A simple design using 4 stubs indicates that it is possible to achieve wider 30 dB return loss matching bandwidths.

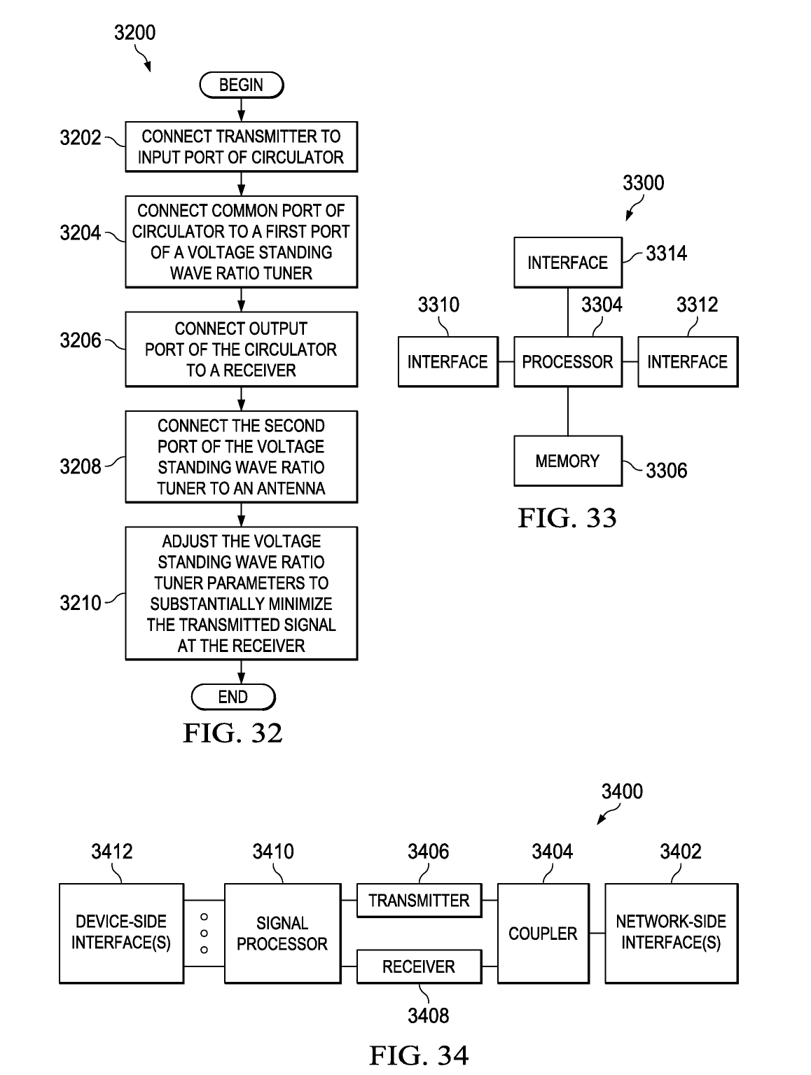

FIG. 32 is a flowchart of an embodiment method 3200 for manufacturing an embodiment FD device. The method 3200 begins at block 3204 where a transmitter is connected to the input port of a circulator. At block 3204, the common port of the circulator is connected to a first port of a VSWR tuner. At block 3206, an output port of the circulator is connected to a receiver. At block 3208, the second port of the VSWR tuner is connected to an antenna 3208. At block 3210, the parameters of the VSWR tuner are adjusted to substantially minimize the transmitted signal at the receiver. The adjustment of the VSWR tuner may be performed as described above. After, block 3210, the method 3200 may end. In an embodiment, the parameters include lumped or distributed impedance elements within the VSWR tuner.

FIG. 33 illustrates a block diagram of an embodiment processing system 3300 for performing methods described herein, which may be installed in a host device. As shown, the processing system 3300 includes a processor 3304, a memory 3306, and interfaces 3310-3314, which may (or may not) be arranged as shown in FIG. 33. The processor 3304 may be any component or collection of components adapted to perform computations and/or other processing related tasks, and the memory 3306 may be any component or collection of components adapted to store programming and/or instructions for execution by the processor 3304. In an embodiment, the memory 3306 includes a non-transitory computer readable medium. The interfaces 3310, 3312, 3314 may be any component or collection of components that allow the processing system 3300 to communicate with other devices/components and/or a user. For example, one or more of the interfaces 3310, 3312, 3314 may be adapted to communicate data, control, or management messages from the processor 3304 to applications installed on the host device and/or a remote device. As another example, one or more of the interfaces 3310, 3312, 3314 may be adapted to allow a user or user device (e.g., personal computer (PC), etc.) to interact/communicate with the processing system 3300. The processing system 3300 may include additional components not depicted in FIG. 33, such as long term storage (e.g., non-volatile memory, etc.).

In some embodiments, the processing system 3300 is included in a network device that is accessing, or part otherwise of, a telecommunications network. In one example, the processing system 3300 is in a network-side device in a wireless or wireline telecommunications network, such as a base station, a relay station, a scheduler, a controller, a gateway, a router, an applications server, or any other device in the telecommunications network. In other embodiments, the processing system 3300 is in a user-side device accessing a wireless or wireline telecommunications network, such as a mobile station, a user equipment (UE), a personal computer (PC), a tablet, a wearable communications device (e.g., a smartwatch, etc.), or any other device adapted to access a telecommunications network.

In some embodiments, one or more of the interfaces 3310, 3312, 3314 connects the processing system 3300 to a transceiver adapted to transmit and receive signaling over the telecommunications network.

FIG. 34 illustrates a block diagram of a transceiver 3400 adapted to transmit and receive signaling over a telecommunications network. The transceiver 3400 may be installed in a host device. As shown, the transceiver 3400 comprises a network-side interface 3402, a coupler 3404, a transmitter 3406, a receiver 3408, a signal processor 3410, and a device-side interface 3412. The network-side interface 3402 may include any component or collection of components adapted to transmit or receive signaling over a wireless or wireline telecommunications network. The coupler 3404 may include any component or collection of components adapted to facilitate bi-directional communication over the network-side interface 3402. The transmitter 3406 may include any component or collection of components (e.g., up-converter, power amplifier, etc.) adapted to convert a baseband signal into a modulated carrier signal suitable for transmission over the network-side interface 3402. The receiver 3408 may include any component or collection of components (e.g., down-converter, low noise amplifier, etc.) adapted to convert a carrier signal received over the network-side interface 3402 into a baseband signal. The signal processor 3410 may include any component or collection of components adapted to convert a baseband signal into a data signal suitable for communication over the device-side interface(s) 3412, or vice-versa. The device-side interface(s) 3412 may include any component or collection of components adapted to communicate data-signals between the signal processor 3410 and components within the host device (e.g., the processing system 3300, local area network (LAN) ports, etc.).

The transceiver 3400 may transmit and receive signaling over any type of communications medium. In some embodiments, the transceiver 3400 transmits and receives signaling over a wireless medium. For example, the transceiver 3400 may be a wireless transceiver adapted to communicate in accordance with a wireless telecommunications protocol, such as a cellular protocol (e.g., long-term evolution (LTE), etc.), a wireless local area network (WLAN) protocol (e.g., Wi-Fi, etc.), or any other type of wireless protocol (e.g., Bluetooth, near field communication (NFC), etc.). In such embodiments, the network-side interface 3402 comprises one or more antenna/radiating elements. For example, the network-side interface 3402 may include a single antenna, multiple separate antennas, or a multi-antenna array configured for multi-layer communication, e.g., single input multiple output (SIMO), multiple input single output (MISO), multiple input multiple output (MIMO), etc. In other embodiments, the transceiver 3400 transmits and receives signaling over a wireline medium, e.g., twisted-pair cable, coaxial cable, optical fiber, etc. Specific processing systems and/or transceivers may utilize all of the components shown, or only a subset of the components, and levels of integration may vary from device to device.

Acronyms used herein include those shown below in Table 3.

TABLE 3

| | |
|---|---|
| ADC | Analog to Digital Converter |
| DAC | Digital to Analog Converter |
| DDC | Digital down-converter |
| DUC | Digital up-converter |
| FD | Full-duplex |
| HPA | High-power power amplifier |
| MIMO | Multiple-input-multiple-output system |
| PA | Power amplifier |
| PSO | Particle swarm optimization |
| Rx | Receive or Receiver |
| SA | Spectrum analyzer |
| SNR | Signal-to-noise power ratio |
| Tx | Transmit or Transmitter |
| VGA | Variable gain attenuator (or amplifier) |
| VNA | Vector network analyzer |

The following references are related to subject matter of the present application. Each of these references is incorporated herein by reference in its entirety:

[1] Philips Semiconductors Application Note AN98035; Circulators and Isolators, Unique Passive Devices, pp 19-21.

[2] Peregrine PE64908 digitally tunable capacitor (DTC) data sheet.

In an embodiment, a system for wireless transmission and reception includes a circulator having a common port, an input port and an output port; a conjugate matching tuner coupled to the common port; and an antenna coupled to the conjugate matching tuner, an impedance of the antenna being conjugate matched to an impedance of the common port of the circulator by the conjugate matching tuner. In an embodiment, the system also includes a transmitter coupled to the input port of the circulator. In an embodiment, the system also includes a receiver coupled to the output port of the circulator. In an embodiment, the transmitter and the receiver are configured for full duplex transmission and reception. In an embodiment, the conjugate matching tuner comprises a voltage standing wave ratio (VSWR) tuner. In an embodiment, the conjugate matching tuner comprises a stub tuner. In an embodiment, the stub tuner comprises one of a sliding stub tuner, a double stub tuner, and a triple stub tuner.

An embodiment network component includes a circulator comprising an input port, a output port, and a common port; a transmitter connected to the input port of the circulator; a voltage standing wave ratio (VSWR) tuner comprising a first port and a second port, the first port connected to the common port of the circulator; a receiver connected to the output port of the circulator; and an antenna connected to the second port of the VSWR tuner, wherein the VSWR tuner substantially minimizes a leak of a transmission signal into the receiver. In an embodiment, the VSWR substantially conjugately matches an impedance of the circulator with an impedance of the antenna. In an embodiment, the VSWR is dynamically adjustable. In an embodiment, the VSWR comprises a stub tuner. In an embodiment, the stub tuner comprises one of a sliding stub tuner, a double stub tuner, and a triple stub tuner. In an embodiment, the transmitter and the receiver are configured for full duplex transmission and reception.

An embodiment method for manufacturing a full duplex system includes connecting a first port of a conjugate matching tuner to a common port of a circulator; and connecting a second port of the conjugate matching tuner to an antenna, an impedance of the antenna being conjugate matched to an impedance of the common port of the circulator by the conjugate matching tuner. In an embodiment, the method also includes connecting a transmitter to an input port of the circulator. In an embodiment, the method also includes connecting a receiver to an output port of the circulator. In an embodiment, the method also includes connecting an output of a vector network analyzer (VNA) to an input port of the circulator; connecting an input of the VNA to an output port of the circulator; sweeping the input port of the circulator with the VNA; and adjusting the conjugate matching tuner for minimum transmission at the output port during the sweeping, thereby conjugate matching the antenna and the common port of the circulator. In an embodiment, the conjugate matching tuner comprises a voltage standing wave ratio (VSWR) tuner. In an embodiment, the conjugate matching tuner comprises a stub tuner. In an embodiment, the stub tuner comprises one of a sliding stub tuner, a double stub tuner, and a triple stub tuner.

An embodiment method for transmitting and receiving a signal in a full duplex wireless device includes transmitting a transmitted signal to an input port of a circulator having a common port, the input port and an output port; and conjugately matching an impedance of the common port of the circulator with an impedance of an antenna thereby reducing reflection of the transmitted signal appearing at the output port of the circulator. In an embodiment, conjuagely matching the impedance of the common port of the circulator with the antenna is accomplished using a conjugate matching tuner placed between the common port of the circulator and the antenna. In an embodiment, the conjugate matching tuner comprises a voltage standing wave ratio (VSWR) tuner. In an embodiment, the conjugate matching tuner comprises one of a stub tuner, a sliding stub tuner, a double stub tuner, and a triple stub tuner.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A system for wireless transmission and reception, comprising:
a circulator having a common port, an input port and an output port;
a conjugate matching tuner coupled to the common port; and
an antenna coupled to the conjugate matching tuner, an impedance of the antenna being conjugate matched to an impedance of the common port of the circulator by the conjugate matching tuner.

2. The system of claim 1, further comprising:
a transmitter coupled to the input port of the circulator; and
a receiver coupled to the output port of the circulator, wherein the transmitter and the receiver are configured for full duplex transmission and reception.

3. The system of claim 1, wherein the conjugate matching tuner comprises a voltage standing wave ratio (VSWR) tuner.

4. The system of claim 1, wherein the conjugate matching tuner comprises one of a stub tuner, a sliding stub tuner, a double stub tuner, and a triple stub tuner.

5. A network component, comprising:
a circulator comprising an input port, a output port, and a common port;
a transmitter connected to the input port of the circulator;
a voltage standing wave ratio (VSWR) tuner comprising a first port and a second port, the first port connected to the common port of the circulator;
a receiver connected to the output port of the circulator; and
an antenna connected to the second port of the VSWR tuner,
wherein the VSWR tuner substantially minimizes a leak of a transmission signal into the receiver.

6. The network component of claim 5, wherein the VSWR substantially conjugately matches an impedance of the circulator with an impedance of the antenna.

7. The network component of claim 5, wherein the VSWR is dynamically adjustable.

8. The network component of claim 5, wherein the VSWR comprises one of a stub tuner, a sliding stub tuner, a double stub tuner, and a triple stub tuner.

9. The network component of claim 5, wherein the transmitter and the receiver are configured for full duplex transmission and reception.

10. A method for manufacturing a full duplex system; the method comprising:
connecting a first port of a conjugate matching tuner to a common port of a circulator; and
connecting a second port of the conjugate matching tuner to an antenna, an impedance of the antenna being conjugate matched to an impedance of the common port of the circulator by the conjugate matching tuner.

11. The method of claim 10, further comprising:
connecting a transmitter to an input port of the circulator.

12. The method of claim 10, further comprising:
connecting a receiver to an output port of the circulator.

13. The method of claim 10, further comprising:
connecting an output of a vector network analyzer (VNA) to an input port of the circulator;
connecting an input of the VNA to an output port of the circulator;
sweeping the input port of the circulator with the VNA; and
adjusting the conjugate matching tuner for minimum transmission at the output port during the sweeping, thereby conjugate matching the antenna and the common port of the circulator.

14. The method of claim 10, wherein the conjugate matching tuner comprises a voltage standing wave ratio (VSWR) tuner.

15. The method of claim 10, wherein the conjugate matching tuner comprises one of a stub tuner, a sliding stub tuner, a double stub tuner, and a triple stub tuner.

16. A method for transmitting and receiving a signal in a full duplex wireless device, the method comprising:
transmitting a transmitted signal to an input port of a circulator having a common port, the input port and an output port; and
conjugately matching an impedance of the common port of the circulator with an impedance of an antenna thereby reducing reflection of the transmitted signal appearing at the output port of the circulator.

17. The method of claim 16, wherein conjuagely matching the impedance of the common port of the circulator with the antenna is accomplished using a conjugate matching tuner placed between the common port of the circulator and the antenna.

18. The method of claim 17, wherein the conjugate matching tuner comprises a voltage standing wave ratio (VSWR) tuner.

19. The method of claim 17, wherein the conjugate matching tuner comprises one of a stub tuner, a sliding stub tuner, a double stub tuner, and a triple stub tuner.
